(19) United States
(12) Patent Application Publication
(10) Pub. No.: US 2011/0281378 A1
(43) Pub. Date: Nov. 17, 2011

(54) ULTRASONIC SYSTEM FOR MEASURING GAS VELOCITY

(75) Inventor: Joachim Doehler, White Lake, MI (US)

(73) Assignee: United Solar Ovonic LLC, Auburn Hills, MI (US)

(21) Appl. No.: 12/780,406

(22) Filed: May 14, 2010

(51) Int. Cl. H01L 21/66; G01F 1/66

(52) U.S. Cl. 438/14; 73/861.27; 118/688; 257/E21.528

(57) ABSTRACT

A system and method for measuring the velocity of gas flow between multiple plasma deposition chambers is provided. A passage atmospherically linking two plasma processing chambers conducts a gas flow therebetween due to differential pressures within the respective chambers. The gas flow velocity is measured by a linear or non-linear ultrasonic energy acoustic path between two transducers located exteriorly to the chambers using the difference in transit time in a forward and reverse direction due to the velocity of gas in the passage. The pressure of process gas in one or more chambers is adjustable based on the measured velocity of gas flow in the passage.

### FIELD OF THE INVENTION

The invention relates generally to measuring fluid flow through a passage. More specifically, the invention relates to an ultrasonic measurement system of fluid flow and its use to monitor gas flow between processing chambers in a continuous processing plasma deposition system.

### BACKGROUND OF THE INVENTION

The high volume production of large area semiconductor devices, such as photovoltaic devices, is often carried out in a continuous deposition process. In processes of this type, one or more webs of substrate material are continuously advanced from a payoff station through a series of deposition chambers wherein various layers of semiconductor material are deposited thereonto, and the substrates are then wound into rolls in a take-up chamber. The deposition process often includes high vacuum conditions.

The layering of deposition species on a substrate in various plasma processing chambers is often performed using chamber specific process gasses, pressures, or temperatures. As a substrate moves between processing chambers, gases may be transmitted between chambers through the webbing slot affecting the processing characteristics of adjacent chambers. Due to the need to transport a continuous layer of substrate material between chambers during processing, it is impossible to fully isolate neighboring processing chambers. Thus, there is a need to measure gas flow between chambers without contributing to unacceptably high levels of interchamber gas contamination.

The prior art used several methods to monitor fluid flow in a passage. These included direct measurement such as by an impeller device, monitoring a pressure differential, measuring thermal transport along moving fluid, or by ultrasonic acoustic measurement systems. Ultrasonic flow meters are often used to measure the flow rate of a fluid in a conduit. Different flow meters are based on several different physics principles. The most commonly used techniques are transit time, Doppler and cross correlation tag. Methods of ultrasonic acoustic measurements are described in U.S. Pat. Nos. 7,637,171; 7,581,453; 3,564,912; 6,732,595; 6,931,945 and Published U.S. patent application Nos. US2005/0245827; US2005/0241411; and US2005/0011279, the contents of each are incorporated herein by reference. These systems commonly use internal placement of transducers such that they are subjected to surrounding fluid. Internal placement of the transducers also requires a large fluid flow passage cross section relative to the beam of ultrasonic energy. In continuous deposition processes a large passage would drastically reduce the interchamber isolation required for efficient plasma deposition. Moreover, internal transducers are more likely to be fouled or damaged by the accumulation of deposition species.

Another solution is to detect the Doppler shift of acoustic waves reflecting off materials, contaminants, particulates, or bubbles within the fluid to determine the velocity of fluid flow as is described by U.S. Pat. No. 7,581,453. This system requires an additional detecting transducer and suffers from the need for highly accurate placement of the transducers in the system. Moreover, this method is not amenable to measurements of gases, particularly at subatmospheric pressures due to the absence of contaminants that will reflect acoustic waves.

As will be explained in detail hereinbelow, the present invention provides systems and methods that are simple in construction, reliable, and which are capable of measuring the velocity of gas flow between plasma deposition chambers at subatmospheric pressure without significantly contributing to interchamber contamination. These and other advantages of the invention will be apparent from the drawings, discussion and description which follow.

### SUMMARY OF THE INVENTION

An inventive system for measuring the velocity of gas flowing at subatmospheric pressure between a first and second plasma processing chamber includes a bulkhead separating the first and second chambers. The system includes a first and second ultrasonic transducer each independently and selectively operative in a transmit mode to transmit ultrasonic energy and a receive mode to receive ultrasonic energy, which generates a signal in response thereto. The first and second ultrasonic transducers are acoustically associated with a gas flow passage which permits gas to flow between the chambers and defines at least a portion of a unidirectional or bidirectional acoustic path extending between first and second ultrasonic transducers.

A controller is provided in electrical communication with the first and second ultrasonic transducers which is independently and selectively operable to route signal to a first or second ultrasonic transducer when in its transmit mode and route electrical signals generated by each transducer when in its receive mode such that ultrasonic energy emitted by a first ultrasonic transducer is receivable by a second ultrasonic transducer and ultrasonic energy emitted by a second ultrasonic transducer is receivable by a first ultrasonic transducer. A signal processor is provided in electrical communication with the first and second ultrasonic transducers wherein the signal processor is operative to receive signals generated by the ultrasonic transducers when in their respective receive modes and process the signals to determine the velocity of gas flowing through the passage.

In particular embodiments of the invention a passage traverses a bulkhead. Optionally, a passage extends from a first chamber to a second chamber without traversing a bulkhead.

The inventive system optionally includes a first acoustic reflector which is disposed in a first chamber and a second acoustic reflector which is disposed in a second chamber whereby the reflectors define at least a portion of the acoustic path external to the passage.

A passage optionally has a constant circular cross section which optionally has a diameter in the range of 2 centimeters to 10 centimeters.

In particular embodiments of the invention, the ultrasonic transducers are disposed exteriorly of the chambers and are optionally associated with the chambers via an ultrasonic energy transmissive window which is aligned with the respective ultrasonic transducers to transmit ultrasonic energy therethrough to the interior of the respective chambers. The windows are optionally made from aluminum, stainless steel, polymer, glass, or combinations thereof. The frequency of ultrasonic energy emitted by either transducer is optionally in the range of 20 kilohertz to 200 kilohertz.

The chambers are optionally plasma deposition chambers wherein a process gas is activated by electromagnetic energy to create a plasma therefrom forming a deposition specie that deposits on a substrate within the chambers. The process gas delivery system optionally maintains a subatmospheric pressure of process gas in the chambers. Subatmospheric pressure is optionally in the range of 1 Torr to 10 Torr.

An acoustic path between a first transducer and a second transducer is optionally linear or nonlinear. Optionally, the length of the acoustic path is longer than the length of the passage.

Also provided is a method for measuring the velocity of gas flowing at subatmospheric pressure between first and second processing chambers wherein the difference in transit time of the ultrasonic energy transmitted by one transducer and received by a second transducer is used to determine the velocity of gas flowing through the passage. The velocity of gas flowing through the passage is optionally used to adjust the pressure of process gas entering the first or second plasma deposition chamber.

### BRIEF DESCRIPTION OF THE DRAWINGS

FIG. 1 represents an embodiment of the inventive system illustrating a passage traversing a bulkhead between plasma processing chambers whereby reflectors are used to define a non-linear acoustic path between a pair of transducers and through the passage;

FIG. 2 represents an embodiment of the invention whereby the non-linear acoustic path is defined by a non-linear passage;

FIG. 3 represents an embodiment of the invention whereby a passage extends external to the chambers and does not traverse a bulkhead;

FIG. 4 represents an embodiment whereby the passage has a linear section that defines a linear acoustic path;

FIG. 5 represents an embodiment of the invention whereby a non-linear acoustic path is defined by reflectors external to a linear passage that does not traverse a bulkhead.

### DETAILED DESCRIPTION OF THE INVENTION

The present invention will be described with reference to systems for measuring gas flow between plasma deposition chambers incorporated into systems for continuously depositing semiconductor material onto a moving web of substrate material. However, it is to be understood that the principles of the present invention may be extended to variously configured ultrasonic flow measurement systems used in other applications where it is desirable to maintain substantial isolation in adjacent chambers during operation. For example, it may be desirable to maintain a condition (e.g. temperature, pressure, composition, etc.) within adjacent chambers. In some applications, it may be desirable to maintain the adjoining area free from contaminating atmosphere elements or contaminants. In other applications, it may be desirable to contain a composition within a chamber and not release portions thereof outside the chamber, for example, not releasing a hazardous gas from within the chamber of the processing system. Further, isolating and maintaining a desirable condition of a processing area without damage to the substrate can save time and resources by optimizing the levels of process gasses and temperatures in each chamber during material deposition by adjustment using knowledge of the level of gas flow between chambers.

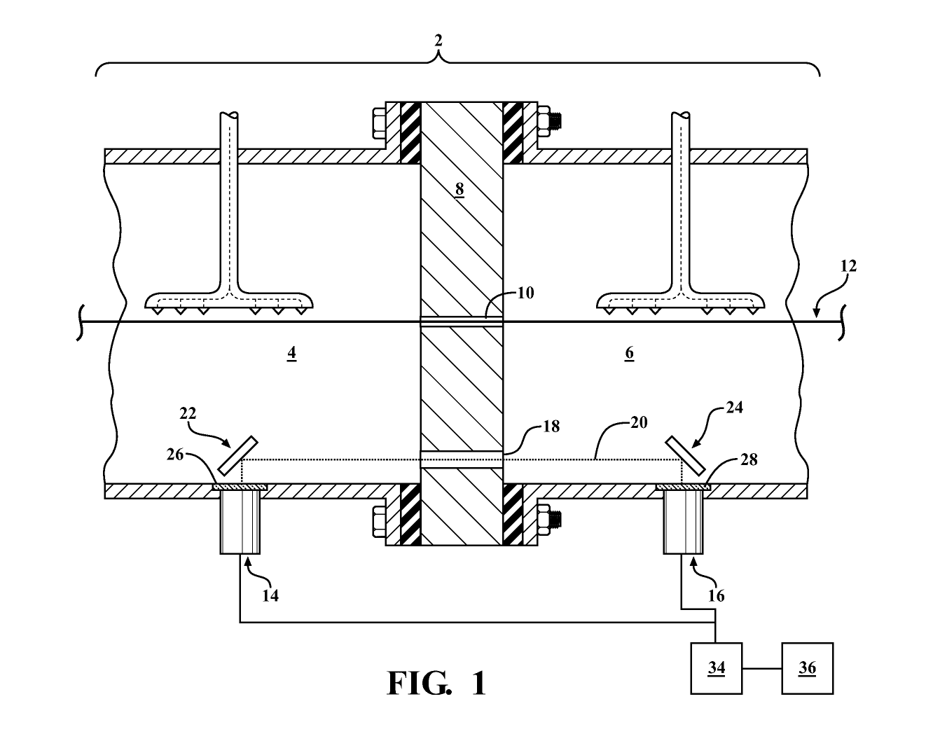

Referring now to FIG. 1, there is shown a perspective view of system 2 for measuring the velocity of a gas flowing at subatmospheric pressures between two plasma processing chambers. The system includes a first plasma processing chamber 4 and a second plasma processing chamber 6, whereby the chambers are separated by a bulkhead 8. The bulkhead 8 includes a slot that allows a webbing substrate 12 to pass through the bulkhead and between the chambers.

A system for measuring the gas flow velocity between chambers includes a first ultrasonic transducer 14 and a second ultrasonic transducer 16. In FIG. 1 the transducers 14, 16 are disposed exteriorly of their respective chambers. This provides the advantages of isolating the transducers from intrachamber gasses and conditions improving transducer cooling and performance. Each of the transducers 14, 16 are independently and selectably operative in a transmit mode and a receive mode. A transmit mode represents active transduction of electrical signal to ultrasonic acoustic energy. A receive mode represents a transducer receiving ultrasonic acoustic energy and generating a signal representative of the received ultrasonic acoustic energy. A signal is illustratively electrical, optical, or other signal type known in the art. When in a transmit mode the transducers 14, 16 will transmit ultrasonic energy and when in a receive mode the transducers 14, 16 will receive ultrasonic energy and generate a signal in response to receiving an ultrasonic signal.

An inventive system includes a passage 18 that interconnects the atmosphere of at least two chambers. The passage 18 permits gas to flow between the chambers 4, 6; this flow is a representative measure of the flow through slot 10. A passage 18 optionally traverses the bulkhead 8 or interconnects the chambers 4, 6 by an external connection. A passage forms at least a portion of a unidirectional or bidirectional acoustic path 20 extending between the transducers 14, 16.

A passage has a cross-section that is optionally circular, rectangular, oval, or any other polygonal or irregular shape. In some embodiments a passage cross-section is of constant dimension. Optionally, a passage cross-section is a constant circular cross-section. The cross-section of a passage 18 is optionally in the range of 2 centimeters to 10 centimeters.

A passage 18 is optionally longitudinally linear, or curvilinear. Optionally, a passage 18 is not linear. When a passage is not linear or curvilinear it optionally is free from sharp angular direction changes to prevent parasitic echoes within the passage 18.

A passage 18 optionally has a length equivalent to the width of the bulkhead 8. Optionally, a passage has a length that is longer than the width of a bulkhead 8. A passage optionally has a length between 0.01 meters and 3 meters. In some embodiments the passage is of sufficient length such that the transit time of a ultrasonic energy is sufficiently longer than the sum of the acoustic energy transmission time plus the relaxation time of the window or transducer itself such that a first transducer and a second transducer optionally transmit ultrasonic energy simultaneously and relax into a receive mode to receive ultrasonic energy and accurately produce a signal. One of ordinary skill in the art can readily calculate a desired length based on the speed of sound in the fluid and the relaxation time of the transducer or window material.

A passage 18 optionally traverses a bulkhead 8 at a position less than 10% the length of the bulkhead 8 from a wall of the first or second chamber. Optionally, the passage is closer to a wall of one or more chambers than is the slot 10.

A passage defines at least a portion of an acoustic path extends from a first transducer 14 to a second transducer 16. An acoustic path is optionally linear or nonlinear. Optionally, an acoustic path is nonlinear. A nonlinear acoustic path is optionally defined by a nonlinear longitudinal length of a passage 18, by the presence of one or more reflectors 22, 24, or combinations thereof.

In some embodiments a non-linear acoustic path 20 is defined by the presence of one or more reflectors present in a chamber. Optionally, a first reflector 22 is disposed in a first chamber 4. A second reflector 24 is optionally disposed in a second chamber 6. In operation, an inventive gas flow measurement system transmits an acoustic wave from a first transducer which is transmitted through the passage and is received by the second transducer 16. When one or more reflectors 22, 24 are present, the nonlinear acoustic path changes direction angularly due to reflection by the one or more acoustic reflectors. Optionally, an acoustic reflector is absent. As illustrated in FIG. 1, a nonlinear acoustic path is defined by a first transducer 14 transmitting ultrasonic energy that is reflected off a first reflector 22 and is directed through the passage 18 whereby it is reflected once again by a second reflector 24 prior to being received by a second transducer 16. Simultaneous or sequential with the transmission of ultrasonic energy by the first transducer 14, the second transducer 16 transmits ultrasonic energy that is reflected off the second reflector 24, is directed through the passage 18, is reflected off the first reflector 22, and is subsequently received by the first transducer 14. It is appreciated that transmission of ultrasonic energy is optionally performed simultaneously by the first transducer 14 and the second transducer 16 whereby the travel time of ultrasonic energy in each direction is sufficiently slow that each transducer can relax so as to be receptive to the ultrasonic energy transmitted by the other transducer. Relaxation times are in the range of 1 msec to 10 msec.

The frequency of the ultrasonic energy emitted by the first or second ultrasonic transducer is of any operable range such that acoustic energy can be transmitted through a gas at subatmospheric pressure. Optionally, the frequency of ultrasonic energy emitted by the first and second ultrasonic transducers is in the range of 20 kilohertz to 200 kilohertz. Optionally, ultrasonic energy is emitted in the range of 50 kilohertz to 100 kilohertz. Illustratively, the wavelength is longer than the molecular mean free path.

Each transducer 14, 16 is optionally coupled to a respective plasma processing chamber via an ultrasonic energy transmissive window. A first transducer 14 is optionally coupled with a first ultrasonic energy transmissive window 26. A second ultrasonic transducer 16 is optionally coupled to a second ultrasonic energy transmissive window 28. The coupling of transducers to an ultrasonic energy transmissive window is optionally via a gel, fluid, or solid coupling agent. Optionally, a coupling agent is a gel. A gel is illustratively SONIGEL, which is illustratively available from Mettler Electronics Corp., Anaheim, Calif. It is appreciated that an ultrasonic coupling agent is any material suitable for the transmission of ultrasonic energy from a transducer to an ultrasonic energy transmissive window. An ultrasonic energy transmissive window 26, 28 is illustratively aluminum, stainless steel, polymer, glass, or combinations thereof. Optionally, an ultrasonic energy transmissive window is a substantially dedicated portion of the wall of a chamber and is continuous with and made from the same material as the wall of the chamber. In some embodiments an ultrasonic energy transmissive window is a material or has a non-stick coating such as Teflon coating that provides resistance to buildup of one or more deposition species or provides simplified removal of the deposition specie within a plasma processing chamber. An ultrasonic energy transmissive window in a first chamber is optionally a different material or has a different coating than an ultrasonic energy transmissive window in a second chamber.

A plasma processing chamber optionally includes a process gas delivery system. A process gas delivery system directs gas from the exterior of a chamber into the interior of a chamber whereby the gas is activated by electromagnetic energy to create a plasma. This plasma forms one or more deposition species that deposit on the substrate within the chamber. The process gas is optionally metered. Metered process gas is maintained at a pressure less than 760 Torr. Optionally, the pressure of process gas within a first chamber 4 or a second chamber 6 is the same. Optionally, process gas delivered by a process gas delivery system is maintained at a different pressure within a first plasma processing chamber 4 or a second plasma processing chamber 6. Optionally, process gas is maintained within a chamber in a pressure range of 1 Torr to 759 Torr including any subdivision thereof. Optionally, a process gas is maintained at an atmospheric pressure of less than 725 Torr. Optionally, a process gas is maintained at an atmospheric pressure of less than 50 Torr. Optionally, the pressure of process gas is substantially maintained at a pressure of about 1 Torr to 10 Torr. It is appreciated that any pressure less than ambient environmental pressure is operable.

An inventive system measures the velocity of a gas moving from one chamber to another chamber and optionally adjusts the pressure or flow rate of one or more process gases moving into a chamber in response to the measured velocity of gas flowing through the passage 18. This system optimizes material deposition on a substrate while simultaneously minimizing contamination of one process gas or deposition specie from a first chamber 4 into a second chamber 6. Optionally, this system controls the amount of intentional mixing between adjacent chambers.

An inventive system includes a controller 34. The controller is in electrical communication with one or more transducers. A controller 34 is in electrical communication with a first transducer 14 and a second transducer 16 wherein the controller 34 is independently and selectively operable to route signal to a first transducer 4 and a second transducer 6 directing each respective transducer to emit ultrasonic energy when in its respective transmit mode. A controller 34 is also independently and selectively operable to route signal generated by either a first transducer 14 or a second transducer 16 when in its respective receive mode such that ultrasonic energy transmitted by an opposite transducer is receivable by an alternate transducer when in its receive mode. A controller 34 is electrically associated with a signal processor 36 that is also in electrical communication with a first and second ultrasonic transducer 4, 6. The signal processor 36 is operative to receive the signals generated by either a first transducer 14 or a second transducer 16 when in its respective receive mode and process the signals so as to determine the velocity of a gas flowing through the passage.

Velocity determination of a gas moving through a passage is optionally determined by the differential and transit time of acoustic energy transmitted in one direction relative to the transit time of acoustic energy transmitted in the opposite direction. Transit time signals are generated in order to calculate the velocity in accordance with transit time methods. Thereby a signal processor illustratively compares the transit time of ultrasonic energy transmitted by a first ultrasonic transducer and received by a second ultrasonic transducer with the transit time of the ultrasonic energy transmitted by the second ultrasonic transducer and received by the first ultrasonic transducer. The time differential is associated with the velocity of fluid flowing through the passage within the bidirectional acoustic path by methods known in the art.

Numerous methods are known in the art for the processing of signals within a signal processor to determine the velocity of a gas flowing through the passage. Such methods are illustratively described in U.S. Pat. No. 7,637,171, the contents of which are incorporated herein by reference. A signal processor is illustratively configured to measure the transit time of the transit time signal and to determine the sound speed of the gas flowing through the conduit which is optionally determined from the transit time, as well as calculate the average velocity of the gas along the transit time paths using the transit time and sound speed.

The absolute transit times of ultrasonic energy transmitted in opposing directions are used to calculate the averaged fluid velocity and the speed of sound in the gas at subatmospheric pressures. A signal processor is configured to calculate these parameters optionally based on the equation:

$${v}_{avg} = {v}_{s} \frac{Δ t}{{t}_{f} + {t}_{r}}$$

Where v_{avg} is the average velocity of gas flow through the passage, vₛ is the velocity of sound in the fluid, Δt is the difference in transit times, t_{f} is the transit time in the forward direction, and tᵣ is the transit time in the reverse direction whereby the equation ignores non-fluid delays. The individual parameters and the calculated velocity and speed of sound in the gas are optionally viewed on a display or used to automatically adjust gas pressure in one or both chambers.

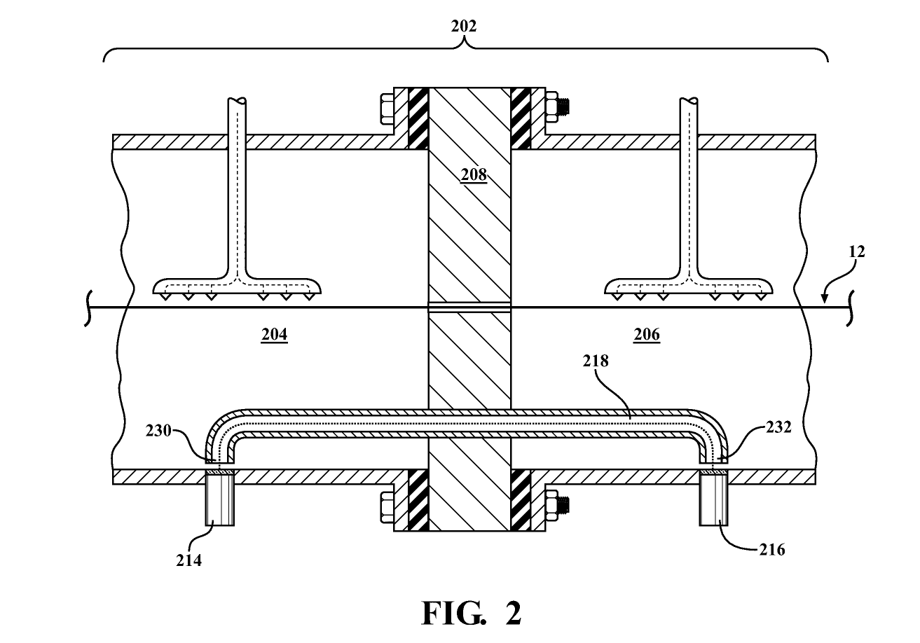

Referring to FIG. 2, an embodiment of an inventive system for measuring the velocity of gas flowing at subatmospheric pressure between a first plasma processing chamber 204 and a second plasma processing chamber 206 is depicted at 202. A nonlinear bidirectional acoustic path is defined by the shape of a passage 218 that traverses a bulkhead 208. The nonlinear acoustic path in all embodiments is optionally longer than the length of the passage. As depicted in FIG. 2, the length of the nonlinear acoustic path is also longer than the length of the acoustic passage 218. Measurement of the velocity of gas flowing from a first chamber 204 to a second chamber through a nonlinear passage is achieved by transmission of ultrasonic energy by a first transducer 214 directed toward a first opening 230 in an acoustic passage 218. The embodiment of FIG. 2 also illustrates a gap between the transducers and the ends of the passage to allow gas to enter and exit the passage. The acoustic energy is directed along the length of the passage throughout the nonlinear curvature of the passage and exits out a second passage opening 232 located in a second plasma processing chamber 206. The transmitted ultrasonic energy is then received by a second ultrasonic transducer 216 associated with the second chamber 206. Simultaneous with or sequential to the transmission of ultrasonic energy by the first transducer 214, ultrasonic energy is transmitted by the second transducer 216 which is transported through the passage 218 and subsequently received by the first transducer 214, thus, defining a bidirectional acoustic path moving through the passage 218 in nonlinear fashion as defined by the nonlinear orientation of the passage 218.

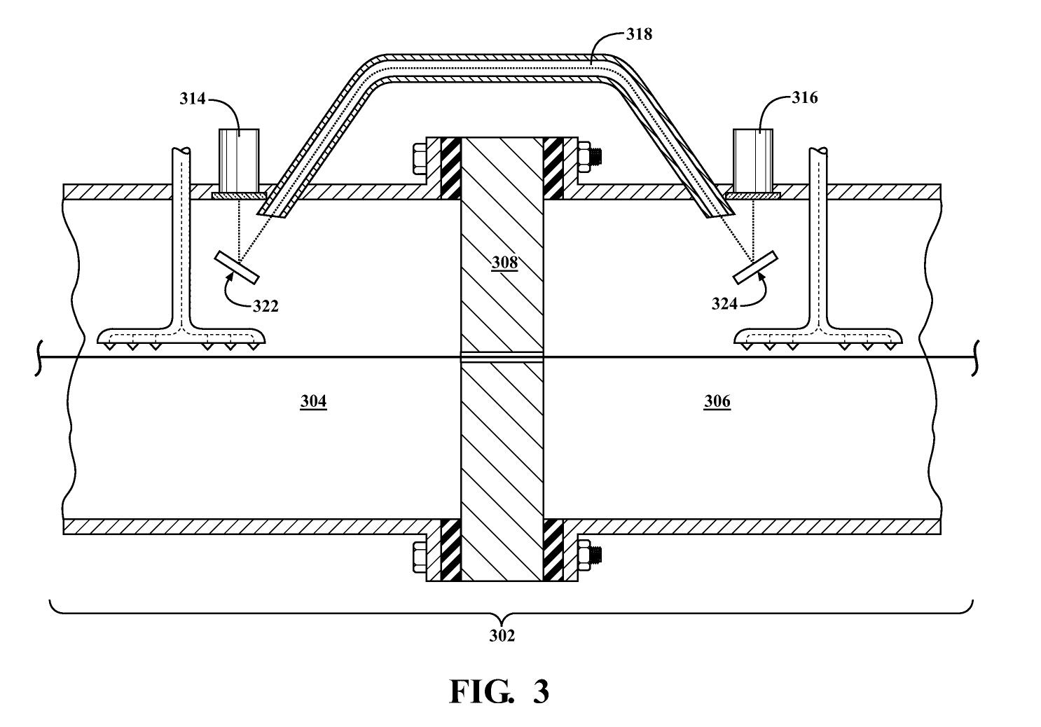

FIG. 3 depicts an embodiment wherein a passage 318 does not traverse a bulkhead 308. In this embodiment, a passage 318 traverses a wall of a first chamber 304 and defines a continuous acoustic path leading to a second chamber 306. A first reflector 322 is optionally disposed between a first transducer 314 and the passage 318. A second reflector is optionally located acoustically intermediate the passage 318 and a second transducer 316 and is disposed in a second chamber 306. As such, a bidirectional acoustic path is directed from a first chamber 304 into a second chamber 306 or alternatively from a second chamber 306 to a first chamber 304 between a first transducer 314 and a second transducer 316. This system offers the advantages of providing a longer acoustic path between the transducers thereby increasing the accuracy of measurements to determine the velocity of gas flowing through the passage between the chambers. A passage 318 optionally is located above a substrate within a plasma processing chamber or below the substrate in a plasma processing chamber. Illustratively, a passage 318 is located above the substrate in a plasma processing chamber such that it exits the top wall of a chamber. This provides the additional advantage of decreasing the level of contamination within the passage due to the presence of deposition debris from the processing gas within the respective chambers and moving through the passage.

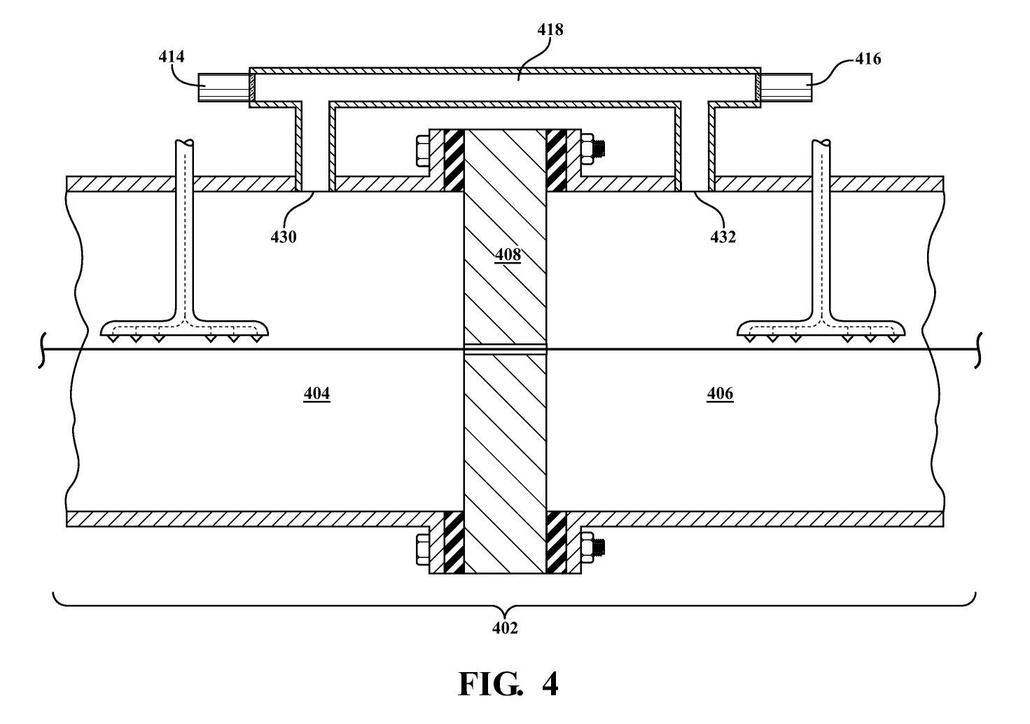

As depicted in FIG. 4, a passage 418 is optionally nonlinear. Illustratively, the passage 418 defines a linear acoustic path between a first transducer 414 and a second transducer 416. As such, the transducers 414 and 416 are illustratively not directly associated with a wall of one or more chambers. This provides the additional advantage of segregating the transducers from the processing chambers and decreasing the operating temperature of each transducer thereby improving the accuracy of the measurement system. Additionally, a first opening 430 of a passage 418 at a second opening 432 of the passage 418 can be located remote from and nearly opposite to a slot which traverses the bulkhead 408 thus maximizing the length of the acoustic path. This configuration also reduces the impact of the presence of a passage on transfer of gas between a first chamber 404 and a second chamber 406 such that the measured velocity of gas flowing through the passage is more representative of gas flowing from a first chamber to a second chamber due to a slot in the bulkhead.

It is appreciated that the length of the acoustic path, either linear or nonlinear, is optionally substantially longer than the length of the cross section of the passage. Optionally, the ratio of the length of the acoustic path to the length of the cross section of the passage is 2:1, 3:1, 5:1, 10:1, 50:1, 100:1, 1,000:1, 10,000:1, or greater.

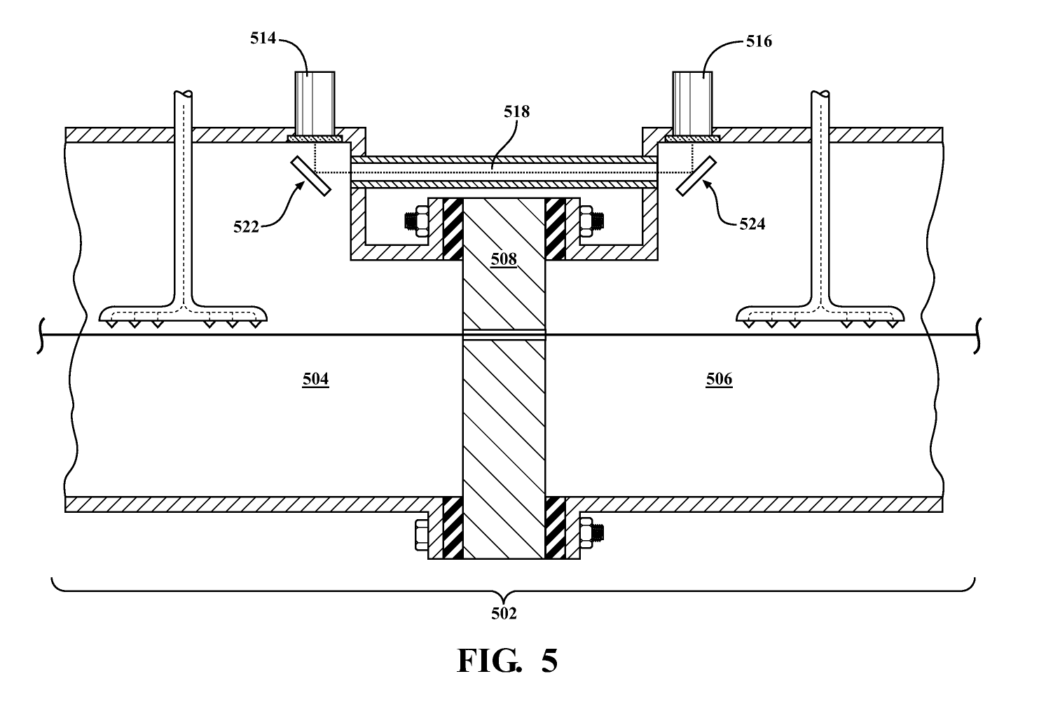

As depicted in FIG. 5, a passage 518 is optionally linear and extends between a first chamber 504 and a second chamber 506 yet does not traverse a bulkhead 508. A nonlinear acoustic path is optionally defined between a first transducer 514 and a second transducer 516 as defined by the position of one or more reflectors 522, 524 whereby the nonlinear acoustic path is transmitted between a first chamber 504 and a second chamber 506 through the passage 518.

Also provided is a method for measuring the velocity of gas flowing at subatmospheric pressure between a first and a second plasma processing chamber. The method includes permitting gas to flow between the chambers through a gas flow passage which defines at least a portion of an acoustic path extending between first and second ultrasonic transducers. The acoustic path is optionally longer than the passage. The transit time of ultrasonic energy transmitted between a first and second ultrasonic transducer as communicated by signals generated by each transducer through a controller into a signal processor is used to calculate the velocity of gas flowing through the passage. Illustratively, processing includes comparing the propagation delay differences between the ultrasonic energy transmitted by that the first ultrasonic transducer and received by the second ultrasonic transducer with that of the ultrasonic energy transmitted by the second ultrasonic transducer and received by the first ultrasonic transducer. It is appreciated that an acoustic path is optionally unidirectional whereby the transit time of ultrasonic energy transmitted from a first transducer and received by a second transducer is used to calculate the fluid flow within a passage. It is appreciated that the propagation delay of the ultrasonic energy transmitted by a first ultrasonic transducer or a second ultrasonic transducer is defined and known such that the change in this delay received by a receiving transducer is in itself sufficient to calculate the fluid flow velocity within the passage by methods known in the art.

Alternatively or in addition, processing includes comparing the transit time of the ultrasonic energy transmitted by a first ultrasonic transducer and received by a second ultrasonic transducer with the transit time of ultrasonic energy transmitted by a second ultrasonic transducer and received by a first ultrasonic transducer. The difference in transit time is subsequently used to determine the velocity of gas flowing through the passage. It is appreciated that measuring the transit time difference cancels out any dimensional changes induced, for instance, by thermal expansion, or by coatings on the windows.

Also provided is a method for depositing material on a substrate whereby the velocity of gas flowing through a passage between a first processing chamber and a second processing chamber is calculated and the measured velocity of the gas is used to adjust the pressure of process gas in either a first or a second plasma deposition chamber so as to maintain a desired differential pressure of gas between the first and second plasma processing chambers. Illustratively, the pressure of gas in a first plasma processing chamber is greater than the pressure of gas in a second plasma processing chamber by a factor of 10%. Illustratively, the pressure of gas in a first plasma processing chamber is greater than the pressure of gas in a second plasma processing chamber by a factor in the range of 1.0001 to 1.2. Optionally, the pressure of gas in a first plasma processing chamber is greater than the pressure of gas in a second plasma processing chamber by a factor in the range of 1.001 to 1.010. This pressure differential will generate a velocity of gas flowing from the first plasma processing chamber to the second plasma processing chamber through the passage at a certain velocity. If the velocity of gas flowing between the chambers exceeds the target velocity by a desired amount, the pressure of the process gas in the first or second plasma deposition chamber is adjusted so as to return the velocity of gas flowing through the passage to the target level. Adjustment of the pressure of process gas is optionally performed manually after viewing the calculated velocity of gas flowing through a passage on a monitor or display, or the system automatically adjusts the pressure of the process gas in one or both chambers to achieve a desired flow rate of gas in the passage.

It is to be understood that yet other embodiments of ultrasonic gas flow measurement systems may be configured in accord with the principles of the present invention in view of the teaching presented herein.

The foregoing has described some specific embodiments of the present invention with regard to their incorporation into a system for the continuous deposition of thin film bodies of semiconductor material. It is to be understood that the present invention may be implemented in various other configurations and may be adapted for other uses. All of such modifications, variations and applications will be apparent to those of skill in the art in view of the teaching presented herein. It is to be understood that the figures of this disclosure are not drawn to scale; rather the figures are drawn to illustrate most clearly the principles of this disclosure discussed herein. The foregoing drawings, discussion and description are illustrative of specific embodiments of the invention, but are not meant to be limitations upon the practice thereof. It is the following claims, including all equivalents, which define the scope of the invention.

1. A system for measuring the velocity of gas flowing, at subatmospheric pressure, between first and second plasma processing chambers, said system comprising:
a bulkhead separating said first and second chambers;
first and second ultrasonic transducers, said ultrasonic transducers each independently and selectably operative in: (i) a transmit mode to transmit ultrasonic energy, and (ii) a receive mode to receive ultrasonic energy and generate a signal in response thereto,
a gas flow passage acoustically associated with said first and second transducers, said passage: (i) permitting gas to flow between said chambers, and (ii) defining at least a portion of a bidirectional acoustic path extending between said first and second ultrasonic transducers;
a controller in electrical communication with said first and second ultrasonic transducers, said controller independently and selectably operable to (i) route signal associated with said first ultrasonic transducer in its transmit mode or its receive mode, and (ii) route signal associated with said second ultrasonic transducer in its transmit mode or its receive mode such that ultrasonic energy emitted by said first ultrasonic transducer is receivable by said second ultrasonic transducer, and ultrasonic energy emitted by said second ultrasonic transducer is receivable by said first ultrasonic transducer;
a signal processor in electrical communication with said first and second ultrasonic transducers, said signal processor operative to: (i) receive the signals generated by said ultrasonic transducers when in their respective receive modes, and (ii) process said signals to determine the velocity of a gas flowing through said passage.

2. The system of claim 1 wherein said passage traverses said bulkhead.

3. The system of claim 1 further comprising a first acoustic reflector disposed in said first chamber, and a second acoustic reflector disposed in said second chamber, said reflectors defining said acoustic path external to said passage.

4. The system of claim 1, wherein the frequency of ultrasonic energy emitted by said first and second ultrasonic transducers is in the range of 20 kHz to 200 kHz.

5. The system of claim 1, wherein the passage has a constant, circular cross section.

6. The system of claim 5, wherein said cross section has a diameter in the range of 2 centimeters to 10 centimeters.

7. The system of claim 1, wherein said ultrasonic transducers are disposed exteriorly of said chambers.

8. The system of claim 1 wherein said chambers each include an ultrasonic energy-transmissive window aligned with respective ultrasonic transducers to transmit ultrasonic energy therethrough, to the interior of their respective chambers.

9. The system of claim 8 wherein said windows are made from aluminum, stainless steel, polymer, glass, or combinations thereof.

10. The system of claim 1, further including a process gas delivery system maintaining a subatmospheric pressure of a process gas in said chambers.

11. The system of claim 10 wherein said pressure is in the range of 1 Torr to 10 Torr.

12. The system of claim 1, wherein said chambers are plasma deposition chambers wherein a process gas is activated by electromagnetic energy to create a plasma therefrom forming a deposition specie that deposits on a substrate in said chambers.

13. The system of claim 1 wherein the distance of said passage from a wall of said first or second chamber is less than 10 percent the length of said bulkhead.

14. The system of claim 1 wherein said acoustic path is non-linear.

15. The system of claim 1 wherein said acoustic path is longer than said passage.

16. A method for measuring the velocity of gas flowing, at subatmospheric pressure, between first and second plasma processing chambers, said method comprising:
providing a bulkhead separating said first and second chambers;
providing a first ultrasonic transducer associated with said first chamber, and a second ultrasonic transducer associated with said second chamber, said ultrasonic transducers each independently and selectably operative in: (i) a transmit mode to transmit ultrasonic energy, and (ii) a receive mode to receive ultrasonic energy and generate a signal in response thereto;
providing a gas flow passage: (i) permitting gas to flow between said chambers, and (ii) defining at least a portion of a bidirectional non-linear acoustic path extending between said first and second ultrasonic transducers, said acoustic path longer than said passage;
providing a controller in electrical communication with said first and second ultrasonic transducers, said controller independently and selectably operable to (i) route signal associated with said first ultrasonic transducer in its transmit mode or its receive mode, and (ii) route signal associated with said second ultrasonic transducer in its transmit mode or its receive mode such that ultrasonic energy emitted by said first ultrasonic transducer is receivable by said second ultrasonic transducer, and ultrasonic energy emitted by said second ultrasonic transducer is receivable by said first ultrasonic transducer;
providing a signal processor in electrical communication with said first and second ultrasonic transducers, said signal processor operative to: (i) receive the signals generated by said ultrasonic transducers when in their respective receive modes, and (ii) process said signals to determine the velocity of a gas flowing through said passage; and
processing said signals in said processor so as to determine the velocity of a gas flowing through said passage.

17. The method of claim 16, wherein the step of processing comprises comparing the transit time of the ultrasonic energy transmitted by the first ultrasonic transducer and received by the second ultrasonic transducer with the transit time of the ultrasonic energy transmitted by the second ultrasonic transducer and received by the first ultrasonic transducer.

18. A method for depositing material on a substrate comprising:
providing a bulkhead separating a first and second plasma deposition chamber;
providing a process gas supply system operative to maintain a pressure of a process gas therein;
providing a first ultrasonic transducer associated with said first chamber, and a second ultrasonic transducer associated with said second chamber, said ultrasonic transducers each independently and selectably operative in: (i) a transmit mode to transmit ultrasonic energy, and (ii) a receive mode to receive ultrasonic energy and generate a signal in response thereto;
providing a gas flow passage: (i) permitting gas to flow between said chambers, and (ii) defining at least a portion of a bidirectional acoustic path extending between said first and second ultrasonic transducers, said acoustic path longer than said passage;
providing a controller in electrical communication with said first and second ultrasonic transducers, said controller independently and selectably operable to (i) route signal associated with said first ultrasonic transducer in its transmit mode or its receive mode, and (ii) route signal associated with said second ultrasonic transducer in its transmit mode or its receive mode such that ultrasonic energy emitted by said first ultrasonic transducer is receivable by said second ultrasonic transducer, and ultrasonic energy emitted by said second ultrasonic transducer is receivable by said first ultrasonic transducer;
providing a signal processor in electrical communication with said first and second ultrasonic transducers, said signal processor operative to: (i) receive signals generated by said ultrasonic transducers when in their respective receive modes, and (ii) process said signals to determine the velocity of a gas flowing through said passage;
processing said signals in said processor to determine the velocity of a gas flowing through said passage; and
adjusting said pressure of said process gas in said first or said second plasma deposition chamber in response to said velocity of said gas flowing through said passage.

19. A multichamber system for the deposition of a layer of a semiconductor material onto an elongated web of a substrate material which is continuously moving through the chambers of said system, comprising:
a first and a second plasma deposition chamber, each chamber including: (i) a process gas supply system operative to maintain a predetermined pressure of a process gas therein, and (ii) a cathode operative to deliver electromagnetic energy to said process gas to create a plasma therefrom, and (iii) a substrate web transport system operative to continuously advance a web of substrate material from said first chamber to said second chamber;
a bulkhead separating said first and second chambers, said bulkhead having a substrate passage defined therethrough permitting said substrate to pass from said first chamber to said second chamber;
a first ultrasonic transducer associated with said first chamber, and a second ultrasonic transducer associated with said second chamber, said ultrasonic transducers each independently and selectably operative in: (i) a transmit mode to transmit ultrasonic energy, and (ii) a receive mode to receive ultrasonic energy and generate a signal in response thereto;
a gas flow passage permitting gas to flow between said chambers through said passage, said passage defining a portion of a bidirectional non-linear acoustic path extending between said first and second ultrasonic transducers and through said gas flow passage, said acoustic path longer than said passage;
a controller in electrical communication with said first and second ultrasonic transducers, said controller independently and selectably operable to (i) route signal associated with said first ultrasonic transducer in its transmit mode or its receive mode, and (ii) route signal associated with said second ultrasonic transducer in its transmit mode or its receive mode such that ultrasonic energy emitted by said first ultrasonic transducer is receivable by said second ultrasonic transducer, and ultrasonic energy emitted by said second ultrasonic transducer is receivable by said first ultrasonic transducer; and
a signal processor in electrical communication with said first and second ultrasonic transducers, said signal processor operative to: (i) receive the signals generated by said ultrasonic transducers when in their respective receive modes, and (ii) process said signals to determine the velocity of a gas flowing through said passage.

20. The system of claim 19 further comprising a first acoustic reflector disposed in said first chamber, and a second acoustic reflector disposed in said second chamber, said reflectors defining said acoustic path external to said passage.
